(19) United States
(12) Patent Application Publication
(10) Pub. No.: US 2024/0347237 A1
(43) Pub. Date: Oct. 17, 2024

(54) BUILT-IN CHIP RESISTOR FOR SUBSTRATE, RESISTOR BUILT-IN MODULE, MANUFACTURING METHOD OF RESISTOR BUILT-IN MODULE, AND TRIMMING

(71) Applicant: KOA Corporation, Ina-shi, Nagano (JP)

(72) Inventors: Tomoki IGUCHI, Ina-shi, Nagano (JP); Miyahito KINOSHITA, Ina-shi, Nagano (JP); Kohji ETO, Ina-shi, Nagano (JP); Tomofumi NOGUCHI, Ina-shi, Nagano (JP)

(21) Appl. No.: 18/579,460

(22) PCT Filed: Jun. 22, 2022
(86) PCT No.: PCT/JP2022/024991

§ 371 Date: Jan. 15, 2024

(30) Foreign Application Priority Data
Jul. 14, 2021 (JP) 2021-116608

(51) Int. Cl. H01C 1/14; H01C 17/245

(52) U.S. Cl. CPC H01C 1/14; H01C 17/245

(57) ABSTRACT

A metal plate resistor that is a built-in chip resistor for substrate has a plate shape including a resistance body, a first electrode bonded to a first end of the resistance body with a first clad portion, and a second electrode bonded to a second end of the resistance body with a second clad portion.

### CROSS-REFERENCE TO RELATED APPLICATIONS

The present application is a 35 U.S.C. § 371 National Stage patent application of International patent application PCT/JP2022/024991, filed on Jun. 22, 2022, which claims priority to Japanese patent application 2021-116608, filed on Jul. 14, 2021.

### TECHNICAL FIELD

The present disclosure relates to a built-in chip resistor for a substrate, a resistor built-in module, a manufacturing method of the resistor built-in module, and a trimming method.

### BACKGROUND

JP2016-86129A discloses a current sensing resistor. This resistor includes a resistance body and electrodes that are respectively bonded to end surfaces of the resistance body.

The resistor is formed to have an abutting structure in which the end surfaces of the resistance body are respectively abutted to end surfaces of the electrodes. The resistance body and the electrodes are bonded by a fusion welding using a laser beam, etc.

### SUMMARY

With such a resistor, beads, which are melting marks, are formed at bonded portions between the resistance body and the electrodes, and a region including the beads is in a state different from that of the original material due to the resistance body and the electrodes that are melted. Because these beads are formed, in the resistor, elevations or undulations of metal is caused on a surface of the resistor due to the melting. If there are the beads causing such elevations or undulations of the metal (collectively referred to as “protrusions and depressions”) on the bonded portions on both ends of the resistance body, the heights and angles of the surfaces of both electrodes may be varied.

In a case in which such a resistor is used by building it into a laminated substrate forming a module, the distance(s) from the electrodes of the resistor to wiring(s) provided directly above or below (directly above and/or below) the electrodes may be varied depending on locations.

Thus, in a case in which a plurality of vias for connecting the above-described wiring(s) to the electrodes are formed, a connection state between the vias and the electrodes may vary depending on the locations where the vias are formed.

An object of the present disclosure is to enable, when a resistor is used by being built into a module, stabilization of a connection state between vias formed in the module and electrodes.

A built-in chip resistor for the substrate according to an aspect of the present disclosure has a plate shape including the resistance body, a first electrode bonded to a first end of the resistance body with a first clad portion, and a second electrode bonded to a second end of the resistance body with a second clad portion.

The built-in chip resistor for the substrate of this aspect is formed of a clad material in which the resistance body is bonded to the first electrode at the first clad portion and the resistance body is bonded to the second electrode at the second clad portion.

Therefore, because of the structure in which the resistance body is bonded to the electrodes by a fusion welding by using a laser, etc., compared with a case in which the beads are formed between the resistance body and the electrodes, it is possible to suppress the height difference between the protrusions and depressions that may be caused on the surface of the chip resistor.

When the built-in chip resistor for the substrate is used by building it into the module, it is possible to suppress the variation in the distances from each of the electrodes to the wiring provided directly above or below (directly above and/or below) each of the electrodes, which may be caused depending on the locations.

Therefore, when the resistor is used by building it into the module, compared with a case in which the distance from the wiring of the module to each of the electrodes varies from location to location, it becomes possible to achieve the stabilization of the connection state between the vias formed in the module and each of the electrodes.

### BRIEF DESCRIPTION OF DRAWINGS

FIG. 1 is a sectional view showing a usage state of a current sensing device according to a first embodiment.

FIG. 2 is a side view showing a metal plate resistor according to the first embodiment.

FIG. 3 is a transparent view of the metal plate resistor according to the first embodiment viewed from the oblique direction.

FIG. 4 is an explanatory diagram showing an example of a manufacturing method of the metal plate resistor according to the first embodiment.

FIG. 5 is an explanatory diagram showing an example of the manufacturing method of the current sensing device according to the first embodiment.

FIG. 6 is an explanatory diagram showing an example of the manufacturing method following FIG. 5.

FIG. 7 is an explanatory diagram showing a clad type resistor that is used in a comparative test.

FIG. 8 is a diagram showing the flatness of the clad type resistor that is used in the comparative test.

FIG. 9 is an explanatory diagram showing a fusion welded type resistor that is used in the comparative test.

FIG. 10 is a diagram showing the flatness of the fusion welded type resistor that is used in the comparative test.

FIG. 11 is a side view showing the metal plate resistor according to a second embodiment.

FIG. 12 is a transparent view of the metal plate resistor according to the second embodiment viewed from the oblique direction.

FIG. 13 is an explanatory diagram of a first base model that is used in the simulation for confirming the effect of the metal plate resistor according to the first embodiment.

FIG. 14 is an explanatory diagram showing a resistance value and a TCR of the first base model.

FIG. 15 is an explanatory diagram showing a state of the simulation that is performed to confirm the effect of the metal plate resistor according to the first embodiment.

FIG. 16 is a diagram showing results of the simulation performed under a first condition.

FIG. 17 is an explanatory diagram showing, in a graph form, the results of the simulations performed under the first condition.

FIG. 18 is a diagram showing the results of the simulations performed under a second condition.

FIG. 19 is an explanatory diagram showing, in a graph form, the results of the simulations performed under the second condition.

FIG. 20 is an explanatory diagram of a second base model that is used in the simulation for confirming the effect of the metal plate resistor according to the second embodiment.

FIG. 21 is an explanatory diagram showing the resistance value and the TCR of the second base model.

FIG. 22 is an explanatory diagram showing a state of the simulation that is performed to confirm the effect of the metal plate resistor according to the second embodiment.

FIG. 23 is a diagram showing the results of the simulations performed under a third condition.

FIG. 24 is an explanatory diagram showing, in a graph form, the results of the simulations performed under the third condition.

FIG. 25 is a diagram showing the results of the simulations performed under a fourth condition.

FIG. 26 is an explanatory diagram showing, in a graph form, the results of the simulations performed under the fourth condition.

### DESCRIPTION OF EMBODIMENTS

### First Embodiment

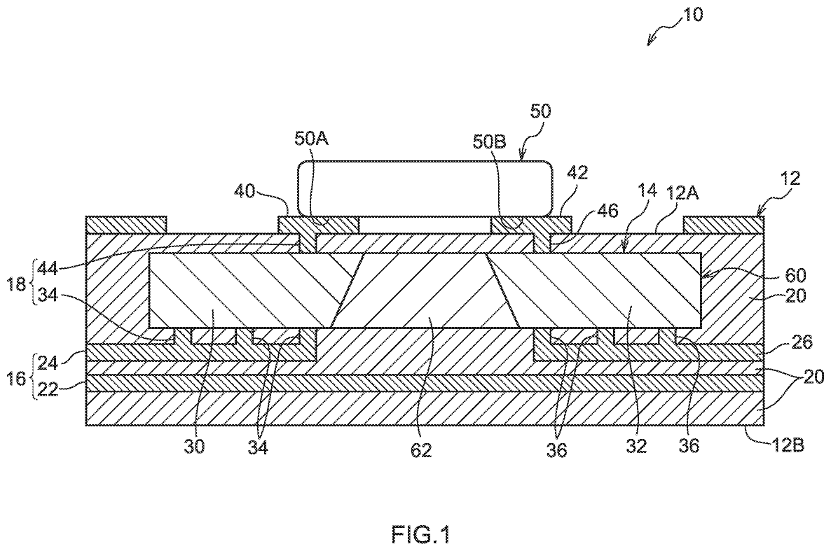

FIG. 1 is a sectional view showing a usage state of a current sensing device 10 according to a first embodiment.

### Current Sensing Device

The current sensing device 10 forms a resistor built-in module. The current sensing device 10 is a device that senses the magnitude of the current flowing through itself. Examples of paths through which the current flows include a wiring in a circuit, a harness extending from a power supply, or a supply path that supplies power to a driving source such as a motor, etc.

The current sensing device 10 is formed on a substrate 12. As an example, the substrate 12 includes a laminated substrate, on which an electric circuit is formed, and the current sensing device 10 senses the current flowing through a printed wiring formed on the laminated substrate.

The current sensing device 10 is provided with the substrate 12 and a metal plate resistor 14 that is arranged in the substrate 12 in a state in which the current sensing device 10 is embedded in the substrate 12. The metal plate resistor 14 is arranged between upper and lower layers of the substrate 12. The metal plate resistor 14 forms a built-in chip resistor for a substrate that is built into the module.

In the substrate 12, wiring portions 16 that extend along a surface of the substrate 12 and via portions 18 that extend in the thickness direction of the substrate 12 are formed.

The substrate 12 includes a plurality of insulating layers 20, and the insulating layers 20 are formed of resin or ceramic, for example. The wiring portions 16 are formed of a metal having an electrically conductive property, and as an example, the wiring portions 16 are formed of copper, silver, or the like by a screen printing, crimping, or the like. The via portions 18 are formed of a metal having the electrically conductive property, and as an example, the via portions 18 are each formed to have a columnar shape by filling a through hole with the electrically conductive metal, such as copper, silver, or the like, by a plating process, or the like.

Specifically, a lower layer wiring 22 extending along the surface of the substrate 12 is formed on a part of the substrate 12 on a lower surface side. A current input wiring 24 and a current output wiring 26 are formed above the lower layer wiring 22 via the insulating layer 20.

A tip end of the current input wiring 24 and a tip end of the current output wiring 26 are arranged so as to be separated from each other. A tip end portion of the current input wiring 24 reaches a lower portion of a first electrode 30 that is formed on the first end side of the metal plate resistor 14. A tip end portion of the current output wiring 26 reaches a lower portion of a second electrode 32 that is formed on the second end side of the metal plate resistor 14.

A plurality of current input vias 34 are formed between the tip end portion of the current input wiring 24 and the first electrode 30 of the metal plate resistor 14, and the current input wiring 24 and the first electrode 30 are electrically connected by the plurality of current input vias 34. Current output vias 36 are formed between the tip end portion of the current output wiring 26 and the second electrode 32 of the metal plate resistor 14, and the current output wiring 26 and the second electrode 32 are electrically connected by the plurality of current output vias 36.

A front surface 12A of the substrate 12 is formed with lands (40 and 42) on which a electronic component, etc. is bonded by soldering. The lands (40 and 42) are respectively connected to a first detection via 44 that is arranged above the first electrode 30 of the metal plate resistor 14 and a second detection via 46 that is arranged above the second electrode 32.

On the front surface 12A of the substrate 12, as an example, an element 50 such as an operational amplifier, etc. is mounted.

### Metal Plate Resistor

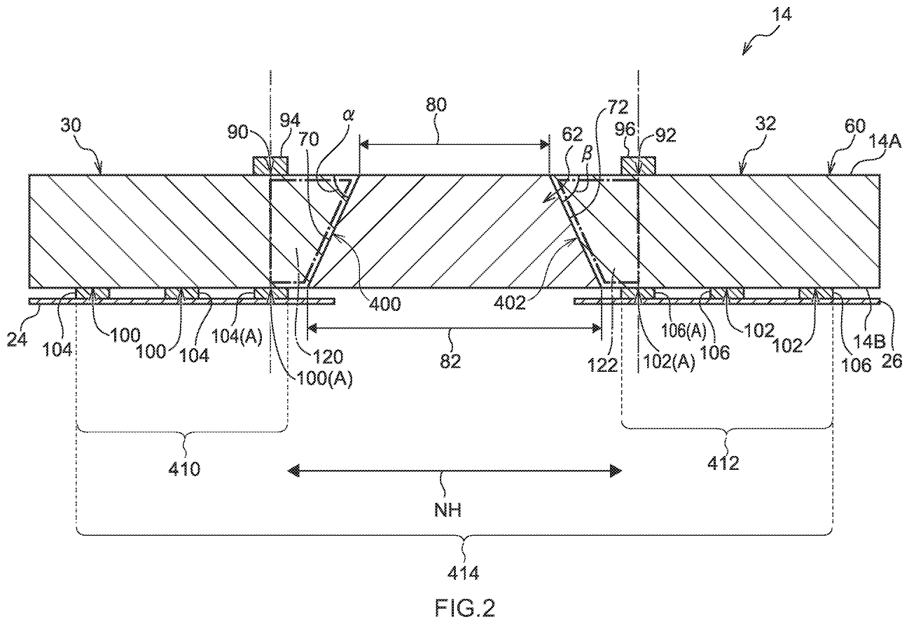

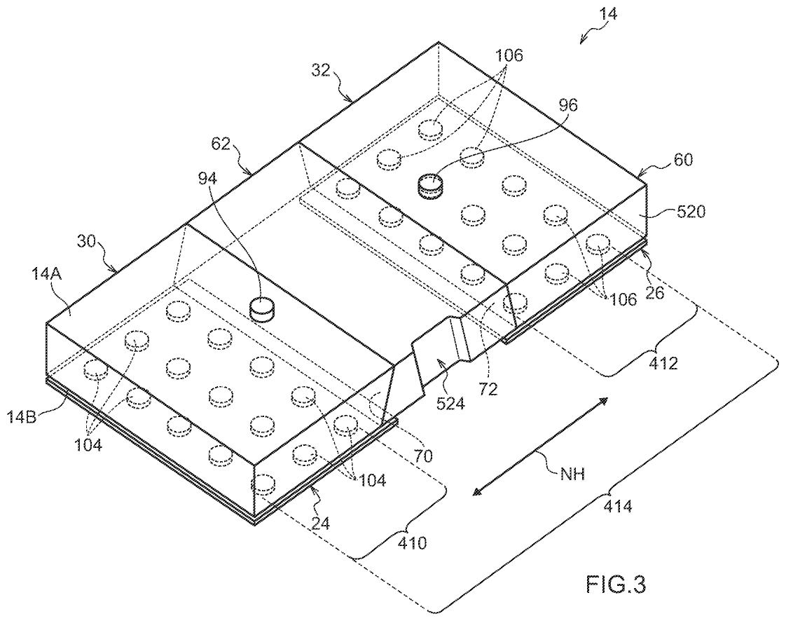

FIG. 2 is a side view showing the metal plate resistor 14 forming the built-in chip resistor for the substrate according to the first embodiment. FIG. 3 is a transparent view of the metal plate resistor according to the first embodiment viewed from the oblique direction.

A resistor main body 60 of the metal plate resistor 14 in the substrate 12 described above is provided with, as shown in FIGS. 2 and 3, a resistance body 62 and electrodes (30 and 32) that are bonded to end surfaces of the resistance body 62 and arranged side by side with the resistance body 62.

The resistance body 62 and the first electrode 30 are fixed by compression bonding processing by a thermocompression bonding. The bonded portion between the resistance body 62 and the first electrode 30 forms a first clad portion 400. The first clad portion 400 is a bonded portion where atoms of the material forming the resistance body 62 and atoms of the material forming the first electrode 30 are mutually diffused and diffusion bonded.

As a result, the material forming the resistance body 62 and the material forming the first electrode 30 are fixed firmly, and good electric characteristics are achieved. In addition, because the fusion welding using a laser, etc. is not used for the bonding, beads resulting from melting marks are not formed, and so, the outer surface of the bonded portion becomes a smooth surface with suppressed protrusions and depressions.

The resistance body 62 and the second electrode 32 are fixed by the compression bonding processing by the thermocompression bonding. The bonded portion between the resistance body 62 and the second electrode 32 forms a second clad portion 402. The second clad portion 402 is a bonded portion where the atoms of the material forming the material forming the resistance body 62 and the atoms of the material forming the second electrode 32 are mutually diffused and diffusion bonded.

As a result, the material forming the resistance body 62 and the material forming the second electrode 32 are fixed firmly, and good electric characteristics are achieved. In addition, because the fusion welding using a heat is not used for the bonding, the protrusions and depressions are suppressed at the bonded portion, and the outer surface becomes a smooth surface.

In the resistor main body 60 that is formed by including the resistance body 62 and the electrodes (30 and 32), the bonded surfaces between the resistance body 62 and the electrodes (30 and 32) are not perpendicular to the alignment direction NH of the resistance body 62 and the electrodes (30 and 32), but are inclined. Specifically, the bonded surfaces (70 and 72) between the resistance body 62 and the electrodes (30 and 32) are each inclined towards the alignment direction NH along the thickness direction of the metal plate resistor 14, and the respective thicknesses are uniformly changed at the bonded surfaces (70 and 72).

Note that, in this embodiment, although a description will be given of a case in which the bonded surfaces 70 and 72 between the resistance body 62 and the electrodes 30 and 32 are each inclined towards the alignment direction NH along the thickness direction of the metal plate resistor 14, this embodiment is not limited to this shape. For example, the bonded surfaces 70 and 72 between the resistance body 62 and the electrodes 30 and 32 may each extend in the perpendicular direction with respect to the alignment direction NH of the resistance body 62 and the electrodes 30 and 32.

The electrode (30 and 32) includes the first electrode 30 that is bonded to the first end of the resistance body 62 and the second electrode 32 that is bonded to the second end of the resistance body 62. Each of the electrodes 30 and 32 is formed to have a rectangular plate shape. In addition, the resistance body 62 is also formed to have a rectangular plate shape.

The second end of the first electrode 30 in the longitudinal direction is bonded to the first end of the resistance body 62 in the longitudinal direction. The second end of the resistance body 62 in the longitudinal direction is bonded to the first end of the second electrode 32 in the longitudinal direction. With such a configuration, the resistor main body 60 is formed to have a rectangular plate shape elongated in the alignment direction NH.

The first bonded surface 70 at which the first electrode 30 and the resistance body 62 are bonded is inclined with respect to the alignment direction NH of the resistance body 62 and the electrodes 30 and 32. The angle α formed between a top surface 14A of the metal plate resistor 14 and the first bonded surface 70 is preferably greater than 50 degrees and equal to or less than 70 degrees. In addition, the angle α formed between the top surface 14A of the metal plate resistor 14 and the first bonded surface 70 is more preferably 60 degrees.

The second bonded surface 72 at which the second electrode 32 and the resistance body 62 are bonded is inclined with respect to the alignment direction NH of the resistance body 62 and the electrodes 30 and 32. The angle β formed between the top surface 14A of the metal plate resistor 14 and the second bonded surface 72 is preferably greater than 50 degrees and equal to or less than 70 degrees. In addition, the angle β formed between the top surface 14A of the metal plate resistor 14 and the second bonded surface 72 is more preferably 60 degrees.

Note that it is desirable that the angle α formed between the top surface 14A of the metal plate resistor 14 and the first bonded surface 70 and the angle β formed between the top surface 14A of the metal plate resistor 14 and the second bonded surface 72 be close values that are approximately equal to each other.

### Manufacturing Method of Built-In Chip Resistor for Substrate

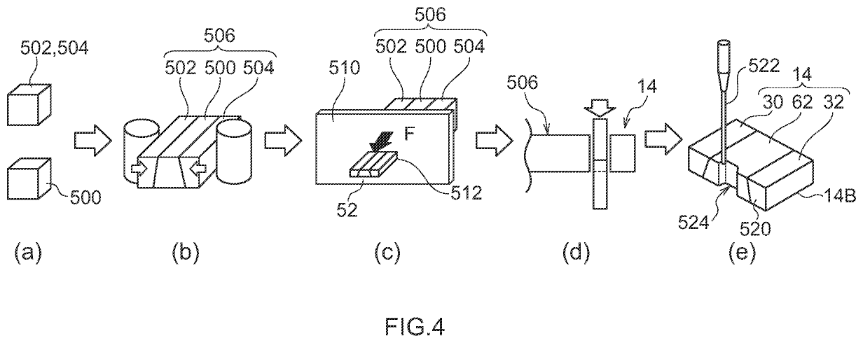

FIG. 4 is an explanatory diagram showing an example of a manufacturing method of the metal plate resistor 14 serving as the built-in chip resistor for the substrate according to the first embodiment.

The manufacturing method includes a preparation step (a) of preparing the materials, a bonding step (b) of bonding the materials, and a processing step (c) of processing the shape. In addition, the manufacturing method of this embodiment includes a fragmenting step (d) of fragmenting the processed intermediate material into individual metal plate resistors 14 by cutting it and a trimming step (e) of adjusting the resistance value of the metal plate resistor 14 by using the laser.

In the preparation step (a) of preparing the material, a resistance body base material 500 serving as a base material of the resistance body 62, an electrode body base material 502 serving as a base material of the first electrode 30, and an electrode body base material 504 serving as a base material of the second electrode 32 are prepared.

In the above, as an example, a material having a trapezoidal cross-sectional shape is used as the resistance body base material 500 of the resistance body 62. As the electrode body base material 502 of the first electrode 30, a material in which a side surface that is to be bonded to the resistance body base material 500 has a surface that is inclined along the inclined surface of the resistance body base material 500 is used. In addition, as the electrode body base material 504 of the second electrode 32, a material in which a side surface that is to be bonded to the resistance body base material 500 has a surface that is inclined along the inclined surface of the resistance body base material 500 is used. Note that the shapes of the respective base materials 500, 502, and 504 are simplified in FIG. 4.

From the viewpoint of the size, the resistance value, and the processability of the metal plate resistor 14, it is preferable to use Cu—Mn alloy as the resistance body base material 500, and to use oxygen-free copper (C1020) as the material of each of the electrode body base materials 502 and 504.

In the bonding step (b) of bonding the materials, the resistance body base material 500 is disposed between the electrode body base materials 502 and 504, and a resistor base material 506 is formed by bonding them by applying pressure in the alignment direction of the base materials 502, 500, and 504.

In other words, in the bonding step (b), so-called cladding (solid phase bonding) is performed between dissimilar metal materials. The respective bonded surfaces between the electrode body base materials 502 and 504 and the resistance body base material 500, which have been subjected to the cladding, each becomes a diffusion bonded surface in which metal atoms derived from both materials are mutually diffused.

As a result, it is possible to firmly bond the resistance body base material 500 with each of the electrode body base materials 502 and 504 at the bonded surface with each other without performing the fusion welding using the laser beam, etc. In addition, good electric characteristics are achieved at the bonded surface between the resistance body base material 500 and each of the electrode body base materials 502 and 504.

In the processing step (c), the resistor base material 506 obtained by performing the cladding is inserted into and passed through an insertion hole 512 of a die 510.

The insertion hole 512 of the die 510 is formed to have a tapered shape such that the diameter thereof is reduced from the entrance towards the exit. The insertion hole 512 is formed to have a rectangular shape in which corner portions are processed to have the chamfered shapes.

By passing the resistor base material 506 through the die 510 having such a shape, it is possible to compressively deform the resistor base material 506 from all directions. As a result, a cross-sectional shape of the resistor base material 506 becomes the shape that imitates the cross-sectional shape of the insertion hole 512 of the die 510.

In the processing step (c), when the resistor base material 506 is to be passed through the die 510, a drawing method in which the resistor base material 506 is drawn out by a holding tool is applied. In the processing step (c), it may be possible to perform a drawing processing by preparing a plurality of dies 510 respectively having the insertion holes 512 with different sizes and by passing the resistor base material 506 through the plurality of dies 510 in a consecutive manner.

In the fragmenting step (d), the metal plate resistor 14 is cut out from the resistor base material 506 so as to achieve the designed width dimension.

By following the above-described steps, it is possible to obtain an individual piece of the metal plate resistor 14 from the resistor base material 506.

In the trimming step (e), the resistance value of the metal plate resistor 14 is set at a desired resistance value by performing the trimming of the resistance body 62 by the irradiation of the laser.

Specifically, a part of the resistance body 62 on a first side surface 520 serving as a second surface extending in the direction intersecting a bottom surface 14B serving as a first surface of the metal plate resistor 14 is melted and processed by using a laser beam 522.

By doing so, a recessed trimming mark 524 is formed at the part of the resistance body 62 on the first side surface 520 serving as the second surface extending in the direction intersecting the bottom surface 14B serving as the first surface of the metal plate resistor 14.

Note that, in this embodiment, although a description will be given of a case in which the first side surface 520 of the resistance body 62 is processed by using the laser beam 522, this embodiment is not limited thereto.

For example, the trimming mark 524 may be formed in the first side surface 520 by stamping the resistance body 62, or the trimming mark 524 may be formed by cutting the first side surface 520 of the resistance body 62 by using a grinder, etc. The trimming step is performed in a case in which the trimming is required.

In addition, in the fragmenting step (d) described above, in a case in which the metal plate resistor 14 is formed by press cutting, burrs may be formed on one of the surfaces of thus-formed metal plate resistor 14 so as to be protruded therefrom. In this case, the other surface on which the burrs are not formed may be used as the surface to which multiple current input vias 34 or multiple current output vias 36 are connected.

In the manufacturing method of the metal plate resistor 14 serving as the built-in chip resistor for the substrate, in the bonding step (b), the base materials 502, 500, and 504 are bonded by the cladding to form the resistance body base material 500 of the metal plate resistor 14.

As a result, as shown in FIGS. 2 and 3, it is possible to ensure a flatness for a region 414 extending from a first connection region 410 provided for the first electrode 30 to a second connection region 412 provided for the second electrode 32.

The resistor main body 60 of the metal plate resistor 14 is formed so as to include the resistance body 62, the first electrode 30, and the second electrode 32. In addition, in the resistor main body 60, the lengths (80 and 82) of the resistance body 62 in the alignment direction NH are different between at the top surface 14A that is located on the one side along the inclination of the bonded surfaces 70 and 72 and the bottom surface 14B that is located on the other side.

In the resistor main body 60, as shown in FIGS. 1 and 2, the resistance body 62 forms a trapezoidal shape (an inverted V-shape) when viewed in a front view, and the area of the resistance body 62 is changed uniformly. The bonded surfaces 70 and 72 between the resistance body 62 and the electrodes 30 and 32 are inclined in opposite directions with respect to the center line of the resistor main body 60. With such a configuration, when viewed in a front view, the resistance body 62 forms a tapered shape.

Specifically, as shown in FIGS. 1 and 2, the lengths of the resistance body 62 in the alignment direction NH have the following relationship in a state in which it is arranged in the substrate 12 (see FIG. 1). The top-surface side length 80 of the top surface 14A that is arranged on the side closer to the front surface 12A of the substrate 12 is shorter than the bottom-surface side length 82 of the bottom surface 14B that is arranged on the side closer to a back surface 12B of the substrate 12.

### Manufacturing Method of Resistor Built-In Module

Next, the manufacturing method of the current sensing device 10 serving as the resistor built-in module will be described. Although there are several possible ways to build the metal plate resistor 14 into the current sensing device 10 serving as the resistor built-in module, an example thereof will be described in this embodiment.

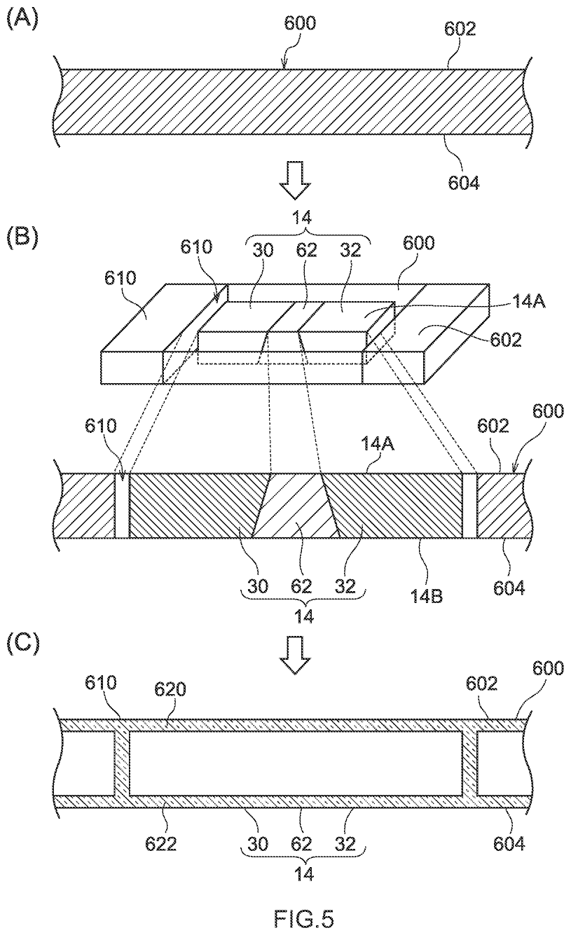

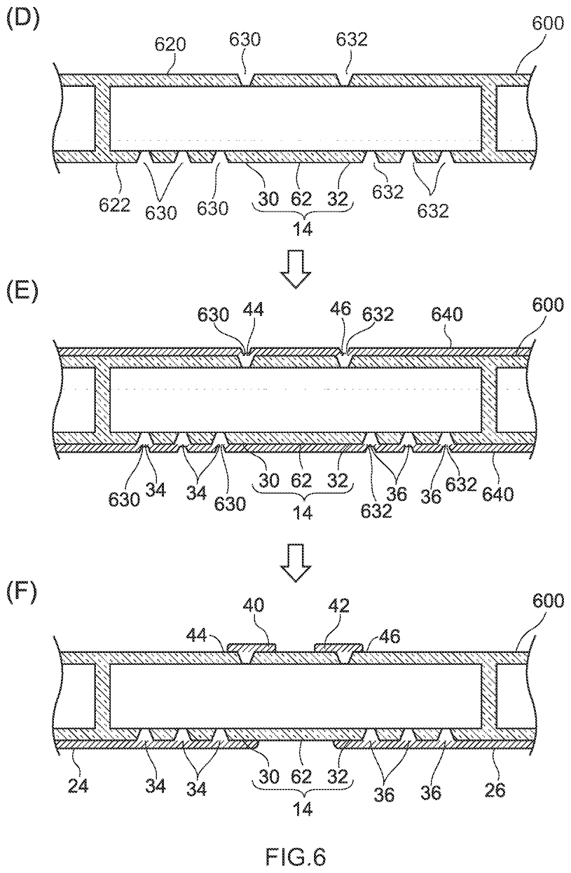

FIG. 5 is an explanatory diagram showing an example of the manufacturing method of the current sensing device according to the first embodiment. FIG. 6 is an explanatory diagram showing an example of the manufacturing method following FIG. 5. In FIG. 6, the cross-sectional shapes of through holes 630 and 632 and the cross-sectional shapes of the vias 34, 36, 44, and 46 respectively formed in through holes 630 and 632 are shown in a deformed manner.

The manufacturing method of the current sensing device 10 includes a preparation step (A) of preparing a substrate 600, an accommodation step (B) of forming an accommodation portion 610 in the substrate 600 and accommodating the metal plate resistor 14, and a layer forming step (C) of forming the layers 620 and 622 on the accommodation portion 610. In addition, the manufacturing method of the current sensing device 10 includes a through hole forming step (D) of respectively forming the through holes 630 and 632 in the layers 620 and 622 of the substrate 600. Furthermore, the manufacturing method of the current sensing device 10 includes a filling step (E) of forming conductive layers 640 on the substrate 600 and filling an electrically conductive material into each of the through holes 630 and 632. The manufacturing method of the current sensing device 10 further includes a patterning step (F) of removing parts of the conductive layers 640 to form patterns on the substrate 600.

As shown in FIG. 5, in the preparation step (A), the substrate 600 made of a resin having an insulating property is prepared. The substrate 600 serves as a base for forming a multi-layer structure.

In the accommodation step (B), the accommodation portion 610 for accommodating the metal plate resistor 14 in the substrate 600 is formed in a predetermined region of the substrate 600.

The metal plate resistor 14 is accommodated in the accommodation portion 610. In this accommodated state, the metal plate resistor 14 is temporarily fixed in the accommodation portion 610 such that the top surface 14A of the metal plate resistor 14 is flush with a primary surface 602 of the substrate 600 and such that the bottom surface 14B of the metal plate resistor 14 is flush with a secondary surface 604 of the substrate 600.

In the layer forming step (C), for example, epoxy resin is applied to the primary surface 602 and the secondary surface 604 of the substrate 600 and cured at a low temperature, thereby forming the first layer 620 on the primary surface 602 of the substrate 600 and the second layer 622 on the secondary surface 604. As a result, the metal plate resistor 14 is sandwiched between the first layer 620 and the second layer 622.

As shown in FIG. 6, in the through hole forming step (D), the first through holes 630 reaching the first electrode 30 of the metal plate resistor 14 are formed in at least one of the first layer 620 and the second layer 622. In addition, the second through holes 632 reaching the second electrode 32 are formed in at least one of the first layer 620 and the second layer 622.

Specifically, in the first layer 620, a pair of the first through hole 630 and the second through hole 632 respectively exposing the surfaces of the first electrode 30 and the second electrode 32 are formed at the locations of the first electrode 30 and the second electrode 32 close to the resistance body 62. In addition, in the second layer 622, the first through holes 630 and the second through holes 632 respectively exposing the surfaces of the first electrode 30 and the second electrode 32 are formed at a plurality of points.

The first through holes 630 and the second through holes 632 are each formed by using a known patterning technique using a laser device, etc.

In the filling step (E), the first through holes 630 and the second through holes 632 are each filled with the electrically conductive material.

Specifically, the conductive layers 640 each made of a metal having the electrically conductive property are formed by plating, etc. on the substrate 600 made of resin on which the first layer 620 and the second layer 622 are formed. The plating is filled into each of the first through holes 630 and each of the second through holes 632.

As a result, the first detection via 44 and the current input vias 34, which are electrically connected to the first electrode 30, are respectively formed in the first through holes 630. In addition, the second detection via 46 and the current output vias 36, which are electrically connected to the second electrode 32, are respectively formed in the second through holes 632.

In the patterning step (F), the lands 40 and 42 are respectively formed around the first detection via 44 and the second detection via 46.

In addition, the current input wiring 24 is formed so as to cover all of the current input vias 34. In addition, the current output wiring 26 is formed so as to cover all of the current output vias 36.

Each of the lands 40 and 42 and each of the wirings 24 and 26 are formed by the patterning step, etc. for partially removing the conductive layers 640 formed on the substrate 600.

On a lower portion of the substrate 600 made of resin, lower layers are formed by the similar steps as described above, and as shown in FIG. 1, the insulating layers 20 and the lower layer wiring 22 are formed.

As shown in FIG. 2, the first detection via 44 formed in the top surface 14A of the first electrode 30 of the metal plate resistor 14 is set at a first detection point 90 for detecting a signal. The second detection via 46 formed in the top surface 14A of the second electrode 32 is set at a second detection point 92 for detecting a signal.

As shown in FIG. 2, a first detection portion 94 is connected to the first detection point 90, and a second detection portion 96 is connected to the second detection point 92. In other words, the first detection portion 94 can be rephrased as the first detection point 90. In addition, the second detection portion 96 can be rephrased as the second detection point 92.

As shown in FIG. 1, in a state in which the metal plate resistor 14 is arranged in the substrate 12, the first detection portion 94 is made of the first detection via 44 that is electrically connected to the first electrode 30. In a state in which the metal plate resistor 14 is arranged in the substrate 12, the second detection portion 96 is made of the second detection via 46 that is electrically connected to the second electrode 32.

As shown in FIG. 3, the first detection portion 94 made of the first detection via 44 is arranged at a single part close to the resistance body 62 at the center of the top surface 14A of the first electrode 30 in the width direction. The second detection portion 96 made of the second detection via 46 is arranged at a single part close to the resistance body 62 at the center of the top surface 14A of the second electrode 32 in the width direction.

In addition, as shown in FIG. 2, for the first electrode 30 and the second electrode 32 of the metal plate resistor 14, input-output points (100 and 102) to which the current flowing through the resistor main body 60 is input/output are set. The input points (100, 102) include current input points 100 set for the first electrode 30 and current output points 102 set for the second electrode 32.

The current input points 100 are set on the bottom surface 14B of the first electrode 30, and the current output points 102 are set on the bottom surface 14B of the second electrode 32. Current input portions 104 are respectively connected to the current input points 100, and current output portions 106 are respectively connected to the current output points 102.

As shown in FIG. 1, in a state in which the metal plate resistor 14 is arranged in the substrate 12, the current input portions 104 are each formed of the current input via 34 that is electrically connected to the first electrode 30. In a state in which the metal plate resistor 14 is arranged in the substrate 12, the current output portions 106 are each formed of the current output via 36 that is electrically connected to the second electrode 32.

As shown in FIG. 3, the current input portions 104 each made of the current input via 34 are arranged at fifteen points on the bottom surface 14B of the first electrode 30. The current input portions 104 are arranged in three rows at equal intervals in the alignment direction NH, and are arranged at five points at equal intervals in the width direction of the metal plate resistor 14 in each row.

The region in which the current input portions 104 are set on the first electrode 30 forms the first connection region 410 where the current input vias 34 are connected to the first electrode 30 (see FIG. 1).

In addition, the current output portions 106 each made of the current output via 36 are arranged at fifteen points on the bottom surface 14B of the second electrode 32. The current output portions 106 are arranged in three rows at equal intervals in the alignment direction NH, and are arranged at five points at equal intervals in the width direction of the metal plate resistor 14 in each row.

The region in which the current output portions 106 are set on the second electrode 32 forms the second connection region 412 where the current output vias 36 are connected to the second electrode 32 (see FIG. 1).

By increasing the number of the current input portions 104 and the current output portions 106 as described above, reliable electrical conduction is ensured.

The metal plate resistor 14 is configured such that the difference between the most protruded part and the most depressed part on the bottom surface 14B (the first surface) of the metal plate resistor 14 is equal to or greater than 0 μm and equal to or less than 100 μm in the region 414 extending from the first connection region 410 to the second connection region 412 with the resistance body 62 being located therebetween. With such a configuration, the metal plate resistor 14 is configured such that the height difference between the protrusions and depressions on the surface of the metal plate resistor 14 is equal to or greater than 0 μm and equal to or less than 100 μm. In addition, it is preferable that the difference between the most protruded part and the most depressed part on the bottom surface 14B of the metal plate resistor 14 be equal to or greater than 0 μm and equal to or less than 50 μm.

It is further preferable that the lower limit value of the difference between the most protruded part and the most depressed part on the bottom surface 14B of the metal plate resistor 14 be equal to or greater than 8 μm. Thus, it is preferable that the difference between the most protruded part and the most depressed part on the bottom surface 14B of the metal plate resistor 14 be equal to or greater than 8 μm and equal to or less than 100 μm, and it is further preferable that the difference be equal to or greater than 8 μm and equal to or less than 50 μm.

Note that, in this embodiment, a description has been given of a case in which, as shown in FIG. 2, the first connection region 410 in which the plurality of current input portions 104 are connected to the bottom surface 14B of the first electrode 30 is provided, and the second connection region 412 in which the plurality of current output portions 106 are connected to the bottom surface 14B of the second electrode 32 is provided. However, this embodiment is not limited to such a configuration.

For example, the first connection region 410 in which the plurality of current input portions 104 are connected to the top surface 14A of the first electrode 30 may be provided, and the second connection region 412 in which the plurality of current output portions 106 are connected to the top surface 14A of the second electrode 32 may be provided.

Also in this case, similarly to the above, the metal plate resistor 14 is configured such that the difference between the most protruded part and the most depressed part on the top surface 14A of the metal plate resistor 14 is equal to or greater than 0 μm and equal to or less than 100 μm in the region 414 extending from the first connection region 410 to the second connection region 412 with the resistance body 62 being located therebetween. In addition, from the viewpoint of uniformity of the contact surfaces between the top surface 14A and each of the vias 44 and 46, it is preferable that the difference between the most protruded part and the most depressed part on the top surface 14A of the metal plate resistor 14 is equal to or greater than 0 μm and equal to or less than 50 μm.

It is further preferable that the lower limit value of the difference between the most protruded part and the most depressed part on the top surface 14A of the metal plate resistor 14 be equal to or greater than 8 μm. Thus, it is preferable that the difference between the most protruded part and the most depressed part on the top surface 14A of the metal plate resistor 14 be equal to or greater than 8 μm and equal to or less than 100 μm, and it is further preferable that the difference be equal to or greater than 8 μm and equal to or less than 50 μm.

In a case in which the current sensing device 10 is formed by arranging the metal plate resistor 14 inside the substrate 12, each of the current input portions 104 is directly connected to the current input wiring 24, and each of the current output portions 106 is directly connected to the current output wiring 26.

In the metal plate resistor 14, a bonding area (120, 122) is formed in the region extending in the alignment direction NH from each of the bonded surfaces 70 and 72 between the resistance body 62 and the electrodes 30 and 32 to the location where the input points (100, 102) are set. The detection point (90, 92) is then set in the bonding area (120, 122).

More specific description will be given with reference to FIG. 2. The first detection point 90 is set in the first bonding area 120 that is the region extending from the first bonded surface 70 at which the resistance body 62 and the first electrode 30 are bonded towards the first electrode 30 side on the one side in the alignment direction NH and up to the location where the current input points 100 are set.

In the above, the boundary on the first end side of the first bonding area 120 is defined by the current input point 100(A) that is arranged at the location closest to the resistance body 62.

In addition, the boundary on the first end side of the first bonding area 120 is defined by an extension line extending in the thickness direction of the metal plate resistor 14 from the center line of the current input portions 104(A) that is connected to the current input point 100(A).

Furthermore, the phrase “the first detection point 90 is set in the first bonding area 120” means that an extension line extending in the thickness direction of the metal plate resistor 14 from the center line of the first detection portion 94 that is connected to the first detection point 90 is located above the first bonding area 120.

In addition, the second detection point 92 is set in the second bonding area 122 extending from the second bonded surface 72 at which the resistance body 62 and the second electrode 32 are bonded towards the other side in the alignment direction NH and up to the location where the current output points 102 are set.

In the above, the boundary on the second end side of the second bonding area 122 is defined by the current output point 102(A) that is arranged at the location closest to the resistance body 62.

In addition, the boundary on the first end side of the second bonding area 122 is defined by an extension line extending in the thickness direction of the metal plate resistor 14 from the center line of the current output portions 106(A) that is connected to the current output point 102(A).

Furthermore, the phrase “the second detection point 92 is set in the second bonding area 122” means that an extension line extending in the thickness direction of the metal plate resistor 14 from the center line of the second detection portion 96 that is connected to the second detection point 92 is located above the second bonding area 122.

### Material

The resistance body 62 of the metal plate resistor 14 is made of a material having a temperature coefficient of resistance (TCR) lower than that of the material forming each of the electrodes 30 and 32.

In the above, the temperature coefficient of resistance (TCR) indicates the rate of change in the resistance value with temperature change. The temperature coefficient of resistance (TCR) can be obtained based on the rate of change in the resistance value and the amount of change in temperature.

For example, for a material body that shows the first resistance value R1 at the first temperature T1 and the second resistance value R2 at the second temperature T2, the temperature coefficient of resistance TCR [ppm/K] is obtained by using the following formula.

TCR=[{(R2−R1)/R1}/(T2−T1)]×1000000

Specifically, each of the electrodes 30 and 32 is made of Cu (copper), for example. In addition, the resistance body 62 is made of a CuMnNi alloy having a lower temperature coefficient of resistance (TCR) than Cu (copper), for example.

Note that, in this embodiment, although a description will be given of a case in which the resistance body 62 is made of a CuMnNi alloy, this embodiment is not limited thereto. The resistance body 62 may be made of, for example, a CuMnSn alloy, a NiCr (nichrome), or CuNi (copper nickel) having a lower temperature coefficient of resistance (TCR) than Cu (copper).

Here, the bonding areas 120 and 122 will be described. Each of the electrodes 30 and 32 has a higher temperature coefficient of resistance (TCR) than the resistance body 62. Therefore, the resistance value and the temperature coefficient of resistance are affected by the electrode material between the input location of the current and a detection terminal in each of the electrodes 30 and 32. Therefore, the area occupied by the electrode material between the input location of the current and the detection terminal, that is, within the shortest detection pitch, affects the resistance value and the temperature coefficient of resistance.

In FIG. 2, when each of the bonding areas 120 and 122 extending from each of the bonded surfaces 70 and 72 to the location where each of the points 100(A) and 102(A) is set is narrowed, the proportion of each of the electrodes 30 and 32, which has a higher temperature coefficient of resistance (TCR), in each of bonding areas 120 and 122 becomes small.

Thus, by narrowing each of the bonding areas 120 and 122, it is possible to reduce the temperature coefficient of resistance (TCR) of the metal plate resistor 14.

In addition, between the detection points 90 and 92, the smaller the proportion of each of the electrodes 30 and 32, in other words, the narrower each of the bonding areas 120 and 122, the smaller the temperature coefficient of resistance (TCR) of the metal plate resistor 14 becomes.

Thus, in this embodiment, the locations of the respective points 90, 92, 100(A), and 102(A) are set so as to be able to reduce the impact of the respective electrodes 30 and 32 on the resistance value of the metal plate resistor 14. In addition, by making each of the bonded surfaces 70 and 72 to be inclined to make each of the bonding areas 120 and 122 narrower, the temperature coefficient of resistance (TCR) of the metal plate resistor 14 as a whole is suppressed.

As described above, with the resistance body 62, in which the top-surface side length 80 and the bottom-surface side length 82 are different, it is possible to set the characteristics of the metal plate resistor 14 by appropriately setting the angles α and β respectively formed by the bonded surfaces 70 and 72, the current paths, and the detection points 90 and 92.

In other words, the angles α and β of the respective bonded surfaces 70 and 72, the locations of the current input point 100(A) and the current output point 102(A) that define the current paths, and the locations of the respective detection points 90 and 92 for detecting the signal are adjusted as parameters for setting the regions of the bonding areas 120 and 122. By doing so, it is possible to achieve the metal plate resistor 14 with desired characteristics.

### Operations and Effects

The metal plate resistor 14 serving as the built-in chip resistor for the substrate of this embodiment is the plate shape including: the resistance body 62; the first electrode 30 bonded to the first end of the resistance body 62 with the first clad portion 400; and the second electrode 32 bonded to the second end of the resistance body 62 with the second clad portion 402.

In this configuration, the metal plate resistor 14 serving as the chip resistor is a clad material in which the resistance body 62 and the first electrode 30 are bonded with the first clad portion 400, and the resistance body 62 and the second electrode 32 are bonded with the second clad portion 402.

Therefore, because of the structure in which the resistance body is bonded to the electrodes by the fusion welding, compared with a case in which the beads, which are the melting marks, are formed between the resistance body and the electrodes, it is possible to suppress the height difference between the protrusions and depressions that may be caused on the surface of the metal plate resistor 14 serving as the chip resistor.

When the metal plate resistor 14 serving as the built-in chip resistor for the substrate is used by building it into the current sensing device 10 serving as the module, it is possible to suppress the variation in the distances from each of the electrodes 30 and 32 to the wiring (the current input wiring 24 and the current output wiring 26 of the wiring portions 16, and each of the lands 40 and 42) provided directly above or below (directly above and/or below) each of the electrodes 30 and 32, which may be caused depending on the locations.

Therefore, when the metal plate resistor 14 is used by building it into the current sensing device 10, compared with a case in which the distance from the above-described wiring (the current input wiring 24 and the current output wiring 26 of the wiring portions 16, and each of the lands 40 and 42) of the current sensing device 10 to each of the electrodes 30 and 32 varies from location to location, it is possible to suppress the variation in the distances from the first end of each of the vias 34, 36, 44, and 46 formed in the current sensing device 10 to each of the electrodes 30 and 32. As a result, it is possible to align the height of each of the vias 34, 36, 44, and 46, and so, it becomes possible to stabilize the connection state between each of the vias 34, 36, 44, and 46 and each of the electrodes 30 and 32.

In the metal plate resistor 14 serving as the built-in chip resistor for the substrate of this embodiment, in the region extending from the first connection region 410 provided for the part of the first electrode 30 to the second connection region 412 provided for the part of the second electrode 32, the difference between the most protruded part and the most depressed part on the first surface of the metal plate resistor 14 is equal to or greater than 0 μm and equal to or less than 100 μm.

In this configuration, it is possible to connect all of the plurality of current input vias 34 to be connected to the first electrode 30 to the first electrode 30 stably, and it is possible to connect all of the plurality of current output vias 36 to be connected to the second electrode 32 to the second electrode 32 stably.

Furthermore, it is possible to make the contact area between the first electrode 30 and each of the current input vias 34 to have the same size as the contact area between the second electrode 32 and each of the current output vias 36. With such a configuration, in the first electrode 30 and the second electrode 32, it is possible to increase the symmetry of the contact areas where each of the vias 34 and 36 are in contact, and so, the flow of the current can be made smoother.

By cladding the resistance body 62 with each of the electrodes 30 and 32, the flatness of the front surface 12A and the back surface 12B of the metal plate resistor 14 is increased. Therefore, the thickness dimension of the metal plate resistor 14 can be made uniform over the entire region, and so, it is possible to suppress the height difference between the protrusions and depressions on the surface of the metal plate resistor 14. Thereby, compared with a case in which the thickness dimension of the metal plate resistor is not uniform, the metal plate resistor 14 is suitable for incorporation into the module.

Furthermore, the beads are not formed between the resistance body 62 and each of the electrodes 30 and 32 as in the case in which the resistance body 62 and each of the electrodes 30 and 32 are subjected to the fusion welding, and the bonded portion between the resistance body 62 and each of the electrodes 30 and 32 is formed linearly. Therefore, it is possible to arrange the vias 34 and 36 at the locations closer to the resistance body 62, and to improve a detection accuracy of the current.

In the current sensing device 10 serving as the resistor built-in module of this embodiment, the metal plate resistor 14 serving as the built-in chip resistor for the substrate is incorporated.

In this configuration, the metal plate resistor 14, in which the resistance body 62 and each of the electrodes 30 and 32 are cladded, is built into the current sensing device 10 serving as the resistor built-in module.

In the metal plate resistor 14, the height difference on the front surface is small. Thus, it is possible to suppress the variation in the distances from the first end of each of the vias 34, 36, 44, and 46 formed in the current sensing device 10 to each of the electrodes 30 and 32 to which each of the vias 34, 36, 44, and 46 is connected. As a result, the stabilization of the connection state is achieved, and so, compared with a case in which the connection state between each of the vias 34, 36, 44, and 46 and each of the electrodes 30 and 32 becomes unstable, it is possible to improve the detection accuracy of the current.

In the metal plate resistor 14 serving as the built-in chip resistor for the substrate of this embodiment, the first clad portion 400 is the bonded portion in which the material forming the resistance body 62 and the material forming the first electrode 30 are diffusion bonded. The second clad portion 402 is the bonded portion in which the material forming the resistance body 62 and the material forming the second electrode 32 are diffusion bonded.

In this configuration, because the resistance body 62 and each of the electrodes 30 and 32 are bonded without performing the fusion welding, the beads, which are the melting marks, are not formed on the bonded portion between the resistance body 62 and each of the electrodes 30 and 32. Therefore, compared with a case in which the beads are formed on the bonded portion between the resistance body 62 and each of the electrodes 30 and 32, it is possible to provide the detection vias 44 and 46 close to the resistance body 62, and so, it is possible to increase the detection accuracy.

The metal plate resistor 14 serving as the built-in chip resistor for the substrate of this embodiment has the trimming mark 524 at the part of the resistance body 62 on the first side surface 520 serving as the second surface extending in the direction intersecting the top surface 14A.

In addition, the trimming method of this embodiment includes the trimming step of processing, in the metal plate resistor 14 serving as the built-in chip resistor for the substrate, the part of the resistance body 62 in the first side surface 520 serving as the second surface extending in the direction intersecting the top surface 14A.

In this configuration, compared with a case in which the trimming mark 524 is formed in the top surface 14A or the bottom surface 14B of the resistance body 62 for adjusting the resistance value, it is possible to suppress the height difference between the protrusions and depressions caused on the top surface 14A or the bottom surface 14B of the metal plate resistor 14. As a result, even after the trimming is performed, the above-described effects are afforded.

In addition, it is possible to manufacture the above-described current sensing device 10 by the manufacturing method of the current sensing device 10 serving as the resistor built-in module.

In addition, in the manufacturing method of the current sensing device 10, in order to incorporate the above-described metal plate resistor 14, each of the through holes 630 and 632 that is formed in each of the layers 620 and 622 can be made close to the same depth (distance).

With such a configuration, compared with a case in which depths of the respective through holes 630 and 632 of the layers 620 and 622 are different and the depths of the respective through holes 630 and 632 are varied, it is possible to stabilize the connection state between each of the vias 34, 36, 44, and 46 formed by each of the through holes 630 and 632 and each of the electrodes 30 and 32.

### Comparative Test

Here, comparative tests were performed to compare the surface flatness by using the resistor that is formed by cladding the resistance body base material 500 and the electrode body base materials 502 and 504 and the resistor that is formed by bonding the resistance body base material 500 and each of the electrode body base materials 502 and 504 by using the laser.

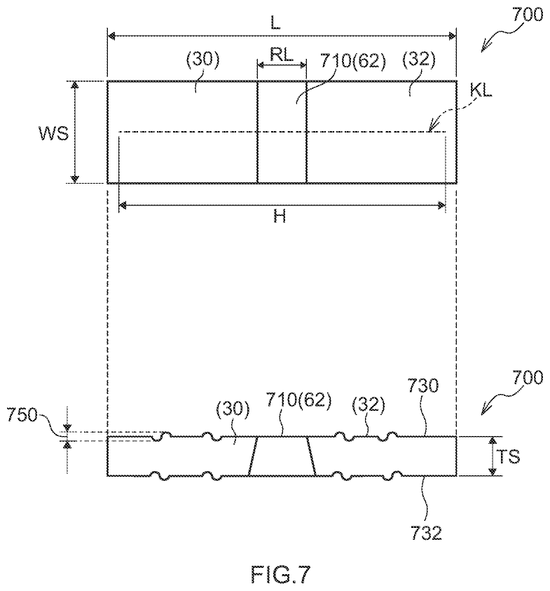

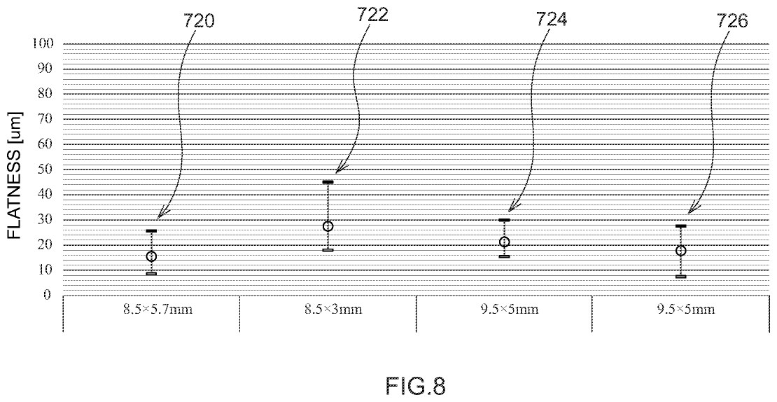

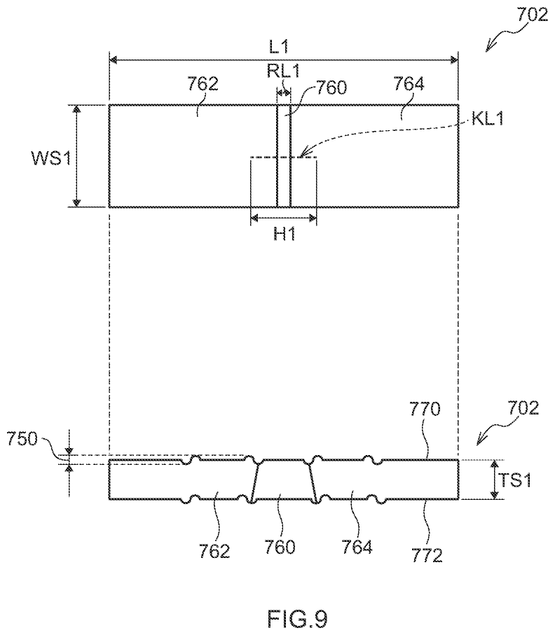

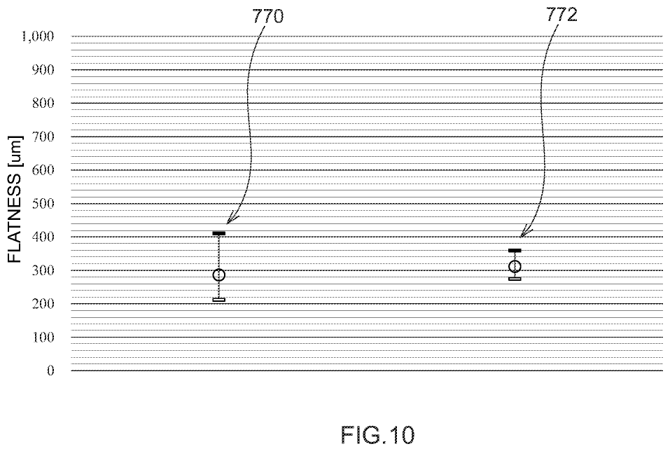

FIG. 7 is an explanatory diagram showing a clad type resistor 700 used in the comparative test. FIG. 8 is a diagram showing the flatness of a clad type resistor used in the comparative test. FIG. 9 is an explanatory diagram showing a fusion welded type resistor 702 used in the comparative test. FIG. 10 is a diagram showing the flatness of a fusion welded type resistor used in the comparative test.

As shown in FIG. 7, as the clad type resistor 700, a sample 720 was prepared with following dimensions: an entire length dimension L of the resistor 700 was 8.5 mm, the length dimension RL of a resistance body 710 was 1.5 mm, the width dimension WS of the resistor 700 was 5.7 mm, and the thickness dimension TS of the resistor 700 was 1.3 mm.

In addition, as the clad type resistor 700, a sample was prepared with following dimensions: an entire length dimension L of the resistor 700 was 9.5 mm, the length dimension RL of the resistance body 710 was 1.5 mm, the width dimension WS of the resistor 700 was 5.0 mm, and the thickness dimension TS of the resistor 700 was 1.3 mm. As samples of this size, for example, a plurality of (specifically, ten) third samples 724 and fourth samples 726 with different manufacture line or date and time, respectively, were prepared.

Other conditions such as material, etc. of the samples 720, 722, 724, and 726 were the same as those of the metal plate resistor 14 in the first embodiment.

On a first top surface 730 and a second bottom surface 732 of each of the samples 720, 722, 724, and 726 in the thickness direction, a straight imaginary line KL extending in the longitudinal direction of the resistor 700 through the center of the resistor 700 in the width direction was assumed. The imaginary line KL extends over a range H of 7 mm centered at the center of the resistor 700 in the longitudinal direction. The range of the imaginary line KL corresponds to the region 414 extending from the first connection region 410 provided on the first electrode 30 to the second connection region 412 provided on the second electrode 32, as shown in FIG. 3.

The difference between the most protruded part and the most depressed part from the surface of the resistor 700 was measured on the imaginary line KL, and the difference was defined as a flatness 750. As a specific measuring method, a laser microscope was used to perform scanning along the imaginary line KL to obtain the height difference.

As shown in FIG. 8, the average value of the flatness 750 of the first samples 720 was about 16 μm, and the average value of the flatness 750 of the second samples 722 was about 28 μm. In addition, the average value of the flatness 750 of the third samples 724 was about 22 μm, and the average value of the flatness 750 of the fourth samples 726 was about 18 μm. In the above, the average values of the flatness 750 are indicated by circles in FIG. 8.

In addition, the flatness 750 of each of the samples 720, 722, 724, and 726 was equal to or greater than 0 μm and equal to or less than 100 μm, and the smallest value of the flatness 750 of each of the samples 720, 722, 724, and 726 was 8 μm.

FIG. 9 is an explanatory diagram showing the fusion welded type resistor 702, which is formed by using the laser, etc., used in the comparative test. FIG. 10 is a diagram showing the flatness 750 of the fusion welded type resistor 702 used in the comparative test.

As shown in FIG. 9, a general surface-mount resistor was used as the fusion welded type resistor 702. For the fusion welded type resistor 702, a plurality of comparative products having following dimensions were prepared: an entire length dimension L1 of the resistor 702 was 50.0 mm, the length dimension RL1 of a resistance body 760 was 5.0 mm, the width dimension WS1 of the resistor 702 was 10.0 mm, and the thickness dimension TS1 of the resistor 702 was 2.0 mm. The number of prepared comparative products was ten.

On a first top surface 770 and a second bottom surface 772 of each of the comparative products in the thickness direction, a straight imaginary line KL1 extending in the longitudinal direction of the resistor 702 through the center of the resistor 702 in the width direction was assumed over a range H1 of 7 mm centered at the center of the resistor 702 in the longitudinal direction. The range of the imaginary line KL1 was set to match the range for each of the samples 720, 722, 724, and 726 described above. In addition, the first top surface 770 is a surface on which a laser beam is incident when the resistance body 760 and the electrodes 762 and 764 are laser welded, and the second bottom surface 772 is a surface from which the laser beam exits after passed through the resistor 702.

The difference between the most protruded part and the most depressed part from each of the surfaces 770 and 772 of the resistor 702 was measured on the imaginary line KL1, and the difference was defined as the flatness 750. As a specific measuring method, the laser microscope was used to perform scanning along the imaginary line KL to obtain the height difference.

As shown in FIG. 10, the average value of the flatness 750 of the first top surface 770 of the resistor 702, that is the comparative product, was about 290 μm, the average value of the flatness 750 of the second bottom surface 772 thereof was about 310 μm. In addition, the smallest value of the flatness 750 of the resistor 702, that is the comparative product, was about 210 μm. The average value of the flatness 750 are indicated by circles in FIG. 10.

From FIGS. 8 and 10, it is understood that the flatness of the resistor is better in the clad type resistor than the fusion welded type resistor.

### Second Embodiment

Next, a metal plate resistor 200 according to a second embodiment will be described with reference to the drawings.

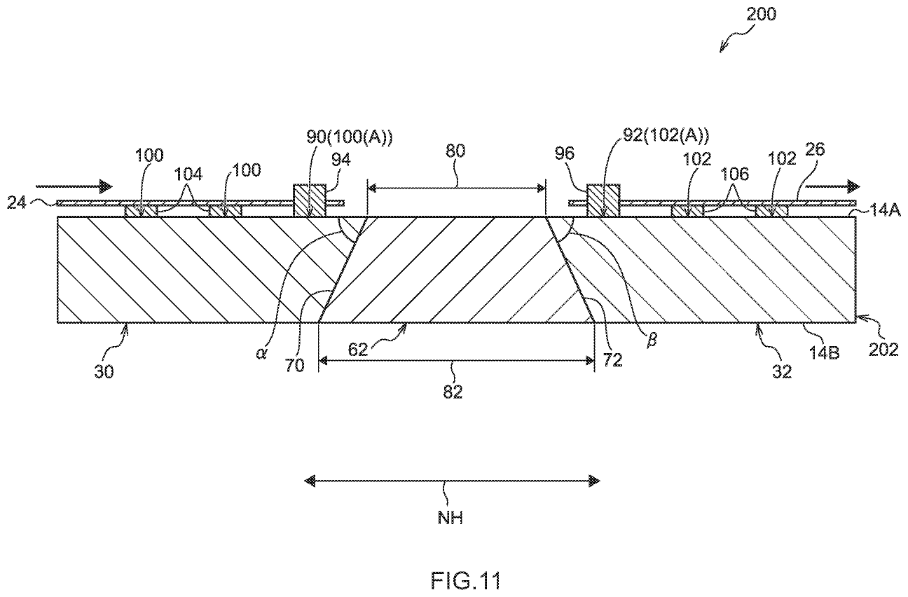

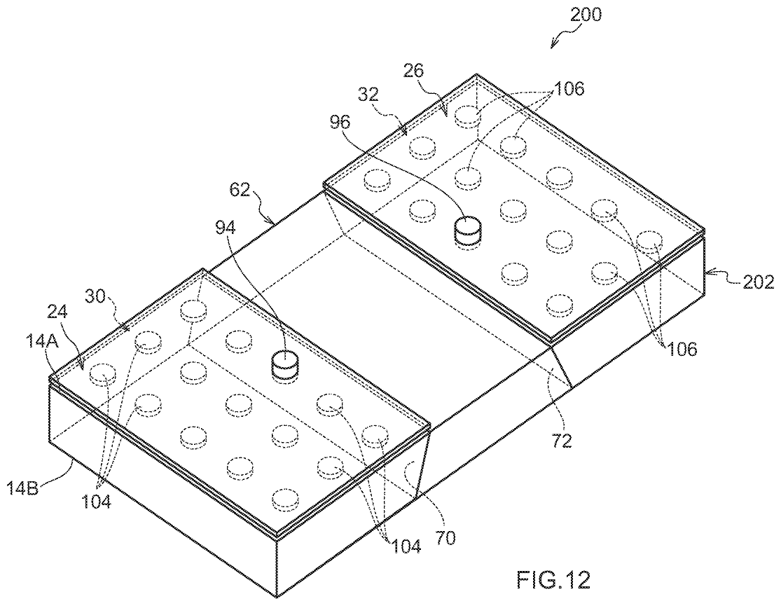

FIG. 11 is a side view showing the metal plate resistor 200 according to the second embodiment. FIG. 12 is a transparent view of the metal plate resistor 200 according to the second embodiment viewed from the oblique direction.

The metal plate resistor 200 according to the second embodiment differs from the first embodiment in that the input points, at which the current flowing through a resistor main body 202 is input, are set on the top surface 14A of the first electrode 30 and the second electrode 32. In this embodiment, components that are the same as or similar to those in the first embodiment will be assigned the same reference numerals, and a description thereof shall be omitted. Description will only be given of components that are different from those in the first embodiment.

The metal plate resistor 200 also forms the current sensing device 10 by being arranged in the substrate 12 in a state in which the metal plate resistor 200 is embedded in the substrate 12 (see FIG. 1).

In the metal plate resistor 200, the first detection portion 94 connected to the first detection point 90 is arranged at a part close to the resistance body 62 at the center of the top surface 14A of the first electrode 30 in the width direction. In addition, the second detection portion 96 connected to the second detection point 92 is arranged at a part close to the resistance body 62 at the center of the top surface 14A of the second electrode 32 in the width direction.

The current input points 100 are set on the top surface 14A of the first electrode 30, and the current output points 102 are set on the top surface 14A of the second electrode 32. The current input portions 104 are respectively connected to the current input points 100, and the current output portions 106 are respectively connected to the current output points 102.

The current input portions 104 are respectively formed of the current input vias 34 connected to the first electrode 30. The current output portions 106 are respectively formed of the current output vias 36 connected to the second electrode 32.

As shown in FIG. 12, the current input portions 104 are arranged at equal intervals on the top surface 14A of the first electrode 30 except for the point at which the first detection portion 94 is arranged. The current output portions 106 are arranged at equal intervals on the top surface 14A of the second electrode 32 except for the point at which the second detection portion 96 is arranged.

The end surfaces of the current input portions 104 are electrically connected to the current input wiring 24. The height of the first detection portion 94 is higher than that of the current input portions 104, and the first detection portion 94 is electrically connected to the current input wiring 24 in a state in which a tip end portion of the first detection portion 94 is protruded from the current input wiring 24.

The end surfaces of the current output portions 106 are electrically connected to the current output wiring 26. The height of the second detection portion 96 is higher than that of the current output portions 106, and the second detection portion 96 is electrically connected to the current output wiring 26 in a state in which a tip end portion of the second detection portion 96 is protruded from the current output wiring 26.

### Operations and Effects

Also in this embodiment, for the configurations that are the same as or similar to those in the first embodiment, it is possible to achieve operational advantages similar to those in the first embodiment.

### Simulation

Next, simulations for confirming the effects of the respective embodiments will be described with reference to the drawings.

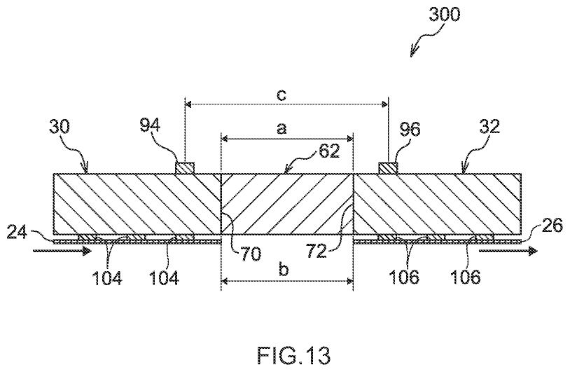

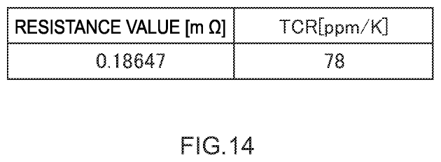

FIG. 13 is an explanatory diagram of a first base model that is used in the simulation for confirming the effect of the metal plate resistor according to the first embodiment. FIG. 14 is an explanatory diagram showing a resistance value and TCR of the first base model.

A first base model 300 is a metal plate resistor indicating a reference for comparison, and it differs from the metal plate resistor 14 of the first embodiment in that the respective bonded surfaces 70 and 72 between the respective electrodes 30 and 32 and the resistance body 62 are perpendicular to the alignment direction NH.

In the first base model 300, for the resistance body 62, the top-surface side length a is 2.7 mm and the bottom-surface side length b is also 2.7 mm. In addition, a detection portion pitch c from the center of the first detection portion 94 to the center of the second detection portion 96 is 4.1 mm.

As shown in FIG. 14, in the first base model 300, the resistance value obtained between the first detection portion 94 and the second detection portion 96 is 0.18647 [m Ω], and the temperature coefficient of resistance (TCR) is 78 [ppm/K].

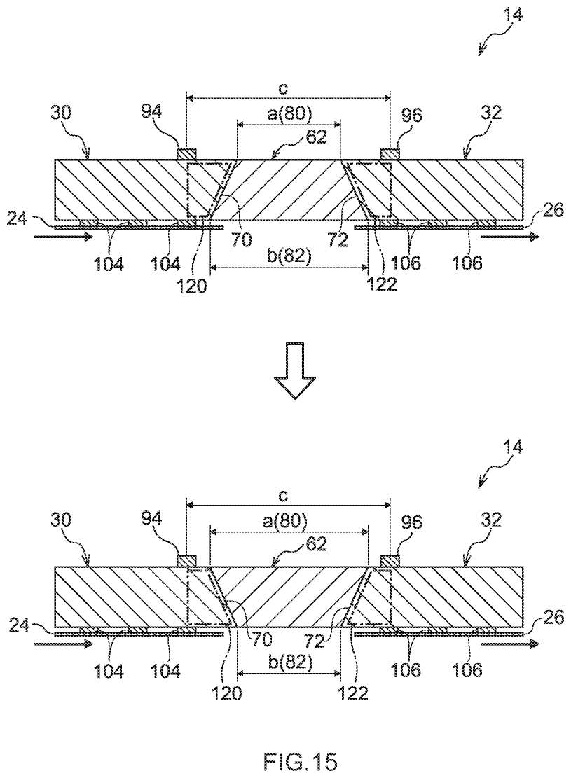

FIG. 15 is an explanatory diagram showing a state of the simulation that is performed to confirm the effect of the metal plate resistor 14 according to the first embodiment. FIG. 15 shows how the top-surface side length a (80) and the bottom-surface side length b (82) of the resistance body 62 change.

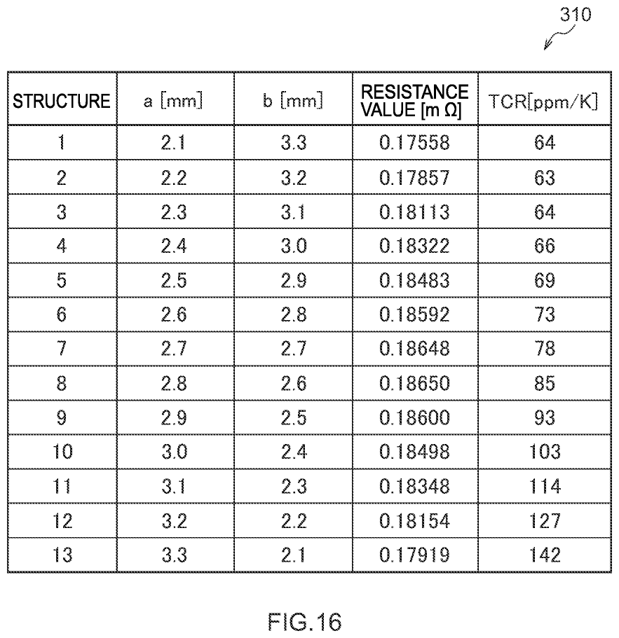

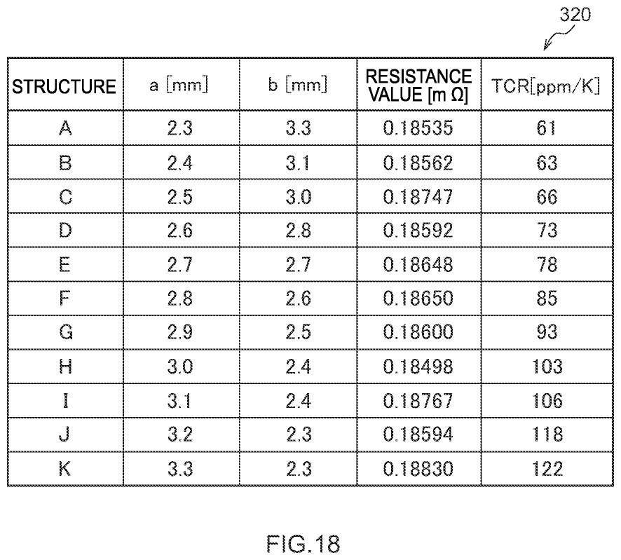

With the metal plate resistor 14 according to the first embodiment, simulations were performed under following first condition 310 (see FIG. 16) and second condition 320 (see FIG. 18).

### First Condition

The first condition 310 of the simulation is shown below. Assume the metal plate resistor 14 having the structures 1 to 13 in which, for the resistance body 62, the top-surface side length a is increased by 0.1 mm from 2.1 mm to 3.3 mm and the bottom-surface side length b is decreased by 0.1 mm from 3.3 mm to 2.1 mm. In each of the structures 1 to 13, the detection portion pitch c is assumed to be the top-surface side length a+1.4 mm.

In the metal plate resistor 14 having the respective structures 1 to 13 shown in FIG. 16, the resistance value obtained between the first detection portion 94 and the second detection portion 96, and the temperature coefficient of resistance (TCR) were respectively obtained by the simulations.

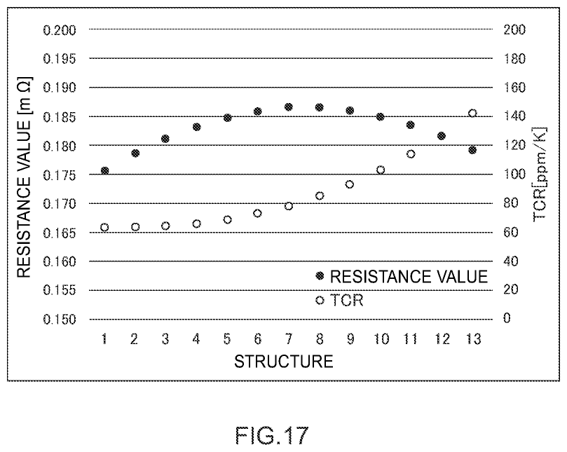

FIG. 16 is a diagram showing the results of the simulations performed under the first condition. FIG. 17 is an explanatory diagram showing, in a graph form, the results of the simulations performed under the first condition.

From FIGS. 16 and 17, with the structures 1 to 6, the temperature coefficient of resistance (TCR) was below 78 [ppm/K], and it was able to confirm that, compared with the first base model 300, the change in the resistance value due to the temperature change can be suppressed and the detection accuracy was improved.

This is considered to be because, compared with the first base model 300, in the metal plate resistor 14 having the structures 1 to 6, the region of each of the bonding areas 120 and 122 was reduced.

### Second Condition

The second condition 320 of the simulation is shown below. Assume the metal plate resistor 14 having the structures A to K in which, for the resistance body 62, the top-surface side length a is increased by 0.1 mm from 2.3 mm to 3.3 mm and the bottom-surface side length b is changed in the range of 3.3 mm to 2.3 mm so that the resistance value between both of the detection portions 94 and 96 becomes equal to that of the first base model 300. In each of the structures A to K, the detection portion pitch c is assumed to be the top-surface side length a+1.4 mm.

In the metal plate resistor 14 having the respective structures A to K, the temperature coefficient of resistances (TCR) were respectively obtained by the simulations.

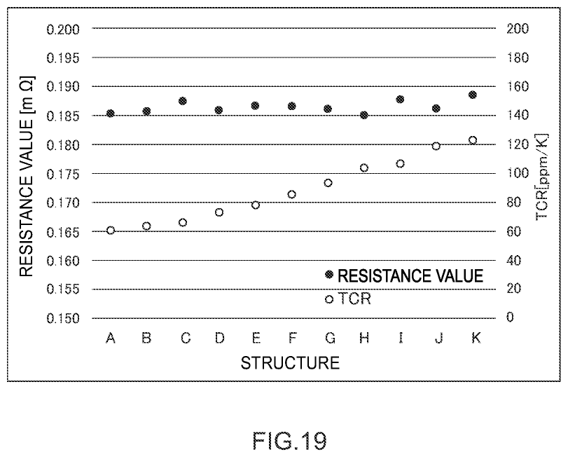

FIG. 18 is a diagram showing the results of the simulation performed under the second condition. FIG. 19 is an explanatory diagram showing, in a graph form, the results of the simulation performed under the second condition.

From FIGS. 18 and 19, with the structures A to D, the temperature coefficient of resistance (TCR) was below 78 [ppm/K], and it was able to confirm that, compared with the first base model 300, the change in the resistance value due to the temperature change can be suppressed and the detection accuracy was improved.

This is considered to be because, compared with the first base model 300, in the metal plate resistor 14 having the structures A to D, the region of each of the bonding areas 120 and 122 was reduced.

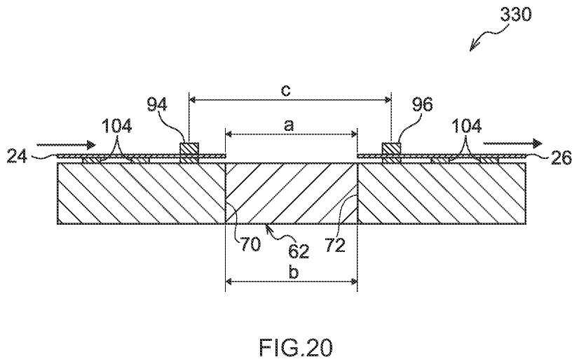

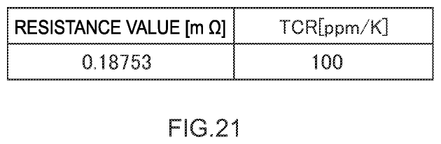

FIG. 20 is an explanatory diagram of a second base model that is used in the simulation for confirming the effect of the metal plate resistor according to the second embodiment. FIG. 21 is an explanatory diagram showing the resistance value and TCR of the second base model.

A second base model 330 is a metal plate resistor indicating a reference for comparison, and it differs from the metal plate resistor 200 of the second embodiment in that in that the respective bonded surfaces 70 and 72 between the respective electrodes 30 and 32 and the resistance body 62 are perpendicular to the alignment direction NH.

In the second base model 330, for the resistance body 62, the top-surface side length a is 2.7 mm and the bottom-surface side length b is also 2.7 mm. In addition, the detection portion pitch c from the center of the first detection portion 94 to the center of the second detection portion 96 is 4.1 mm.

As shown in FIG. 21, in the second base model 330, the resistance value obtained between both of the detection portions 94 and 96 is 0.18753 [m Ω], and the temperature coefficient of resistance (TCR) is 100 [ppm/K].

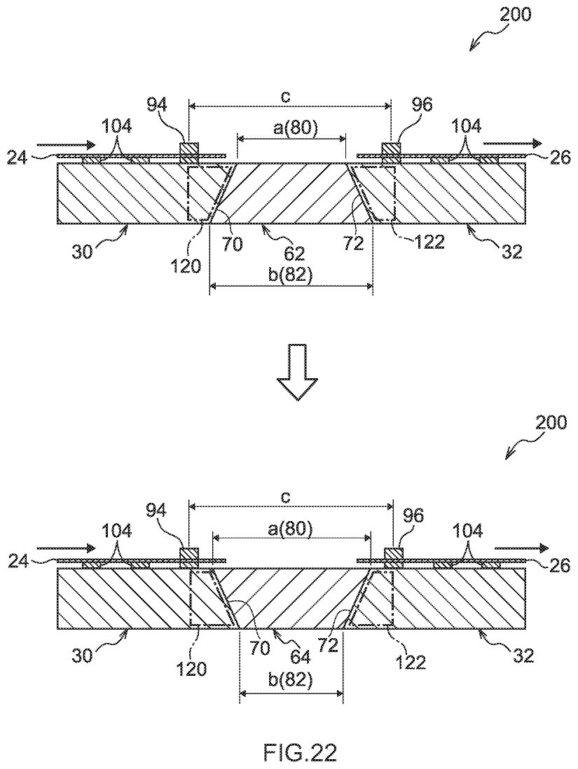

FIG. 22 is an explanatory diagram showing a state of the simulation that is performed to confirm the effect of the metal plate resistor 200 according to the second embodiment. FIG. 22 shows how the top-surface side length a (80) and the bottom-surface side length b (82) of the resistance body 62 change.

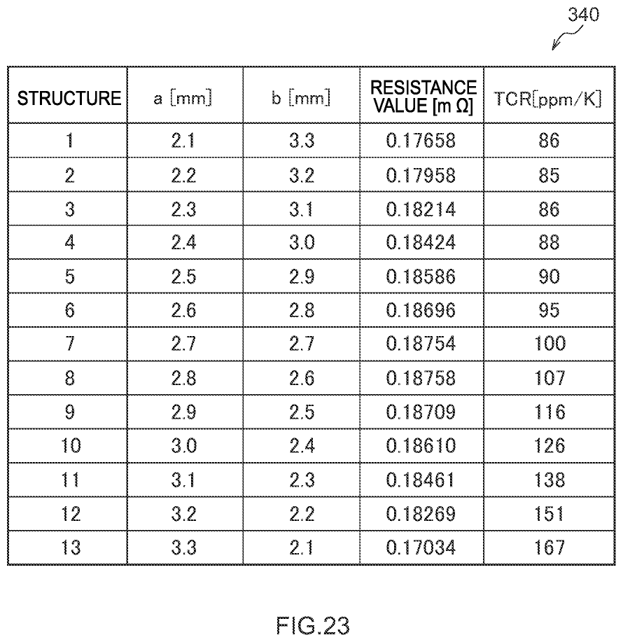

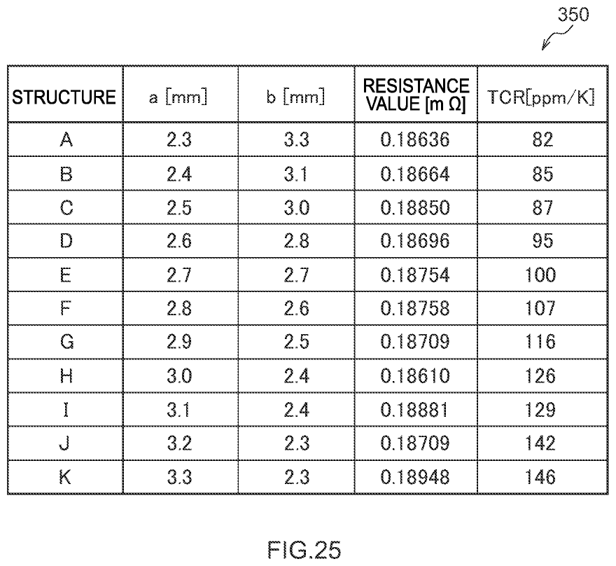

With the metal plate resistor 200 according to the second embodiment, simulations were performed under following third condition 340 (see FIG. 23) and fourth condition 350 (see FIG. 25).

### Third Condition

The third condition 340 of the simulation is shown below. Assume the metal plate resistor 200 having the structures 1 to 13 in which, for the resistance body 62, the top-surface side length a is increased by 0.1 mm from 2.1 mm to 3.3 mm and the bottom-surface side length b is decreased by 0.1 mm from 3.3 mm to 2.1 mm. In each of the structures 1 to 13, the detection portion pitch c is assumed to be the top-surface side length a+1.4 mm.

In the metal plate resistor 200 having the respective structures 1 to 13, the resistance value obtained between the first detection portion 94 and the second detection portion 96, and the temperature coefficient of resistances (TCR) were respectively obtained by the simulations.

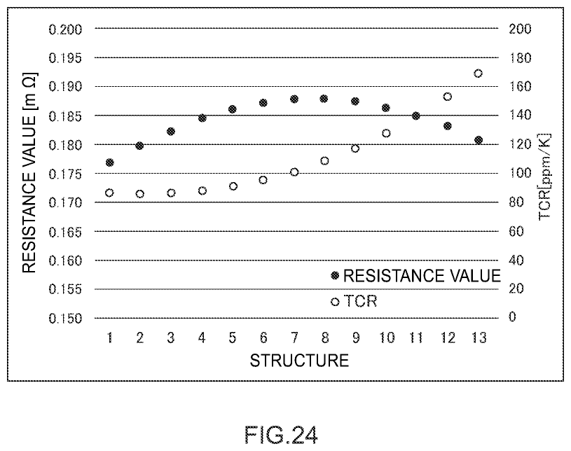

FIG. 23 is a diagram showing the results of the simulations performed under the third condition. FIG. 24 is an explanatory diagram showing, in a graph form, the results of the simulations performed under the third condition.

In FIGS. 23 and 24, in the structures A to D, the temperature coefficient of resistance (TCR) was below 100 [ppm/K], and it was able to confirm that, compared with the second base model 330, the change in the resistance value due to the temperature change can be suppressed and the detection accuracy was improved.

This is considered to be because, compared with the second base model 330, in the metal plate resistor 200 having the structures 1 to 6, the region of each of the bonding areas 120 and 122 was reduced.

### Fourth Condition

The fourth condition 350 of the simulation is shown below. Assume the metal plate resistor 200 having the structures A to K in which, for the resistance body 62, the top-surface side length a is increased by 0.1 mm from 2.3 mm to 3.3 mm and the bottom-surface side length b is changed in the of 3.3 mm to 2.3 mm so that the resistance value between both of the detection portions 94 and 96 becomes equal to that of the second base model 330. In each of the structures A to K, the detection portion pitch c is assumed to be the top-surface side length a+1.4 mm.

In the metal plate resistor 200 having the respective structures A to K, the temperature coefficient of resistances (TCR) were respectively obtained by the simulations.

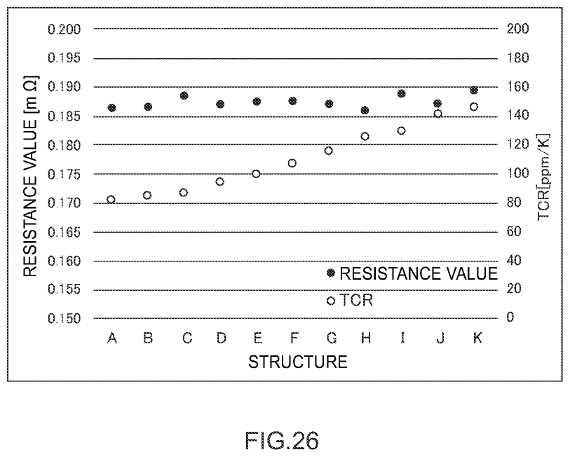

FIG. 25 is a diagram showing the results of the simulations performed under the fourth condition. FIG. 26 is an explanatory diagram showing, in a graph form, the results of the simulations performed under the fourth condition.

From FIGS. 25 and 26, with the structures A to D, the temperature coefficient of resistance (TCR) was below 100 [ppm/K], and it was able to confirm that, compared with the second base model 330, the change in the resistance value due to the temperature change can be suppressed and the detection accuracy was improved.

This is considered to be because, compared with the second base model 330, in the metal plate resistor 200 having the structures A to K, the region of each of the bonding areas 120 and 122 was reduced.

Although the embodiments of the present disclosure have been described in the above, the above-mentioned embodiments merely illustrate a part of application examples of the present disclosure, and the technical scope of the present disclosure is not intended to be limited to the specific configurations of the above-described embodiments.

The present application claims priority to Japanese Patent Application No. 2021-116608, filed in the Japan Patent Office on Jul. 14, 2021. The contents of this application are incorporated herein by reference in their entirety.

### REFERENCE SIGNS LIST

10 current sensing device
14, 200 metal plate resistor
30 first electrode
32 second electrode
62 resistance body
400 first clad portion
402 second clad portion
410 first connection region
412 second connection region
524 trimming mark
620 first layer
622 second layer
630 first through hole
632 second through hole

1. A built-in chip resistor for a substrate having a plate shape comprising:
a resistance body;
a first electrode bonded to a first end of the resistance body with a first clad portion; and
a second electrode bonded to a second end of the resistance body with a second clad portion.

2. The built-in chip resistor for the substrate according to claim 1, wherein
the first clad portion is a bonded portion where the material forming the resistance body and the material forming the first electrode are diffusion bonded, and
the second clad portion is a bonded portion where the material forming the resistance body and the material forming the second electrode are diffusion bonded.

3. The built-in chip resistor for the substrate according to claim 1, wherein
a difference between a most protruded part and a most depressed part on a first surface of the chip resistor is equal to or greater than 0 μm and equal to or less than 100 μm in a region extending from a first connection region provided for a part of the first electrode to a second connection region provided for a part of the second electrode.

4. The built-in chip resistor for the substrate according to claim 3, wherein
the resistance body has a trimming mark in a part on a second surface extending in a direction intersecting the first surface.

5. A resistor built-in module into which the built-in chip resistor for the substrate according to claim 1 is built.

6. A manufacturing method of resistor built-in module into which the built-in chip resistor for the substrate according to claim 1 is built, the method comprising:
a layer forming step of forming a first layer and a second layer so as to sandwich the chip resistor;
a through hole forming step of forming a first through hole reaching the first electrode in at least one of the first layer and the second layer and forming a second through hole reaching the second electrode in at least one of the first layer and the second layer; and
a filling step of filling an electrically conductive material into the first through hole and the second through hole.

7. A trimming method comprising a trimming step of processing, in the built-in chip resistor for the substrate according to claim 3, a part of the resistance body in a second surface extending in a direction intersecting the first surface.
